(19) United States
(12) Patent Application Publication
(10) Pub. No.: US 2011/0308612 A1
(43) Pub. Date: Dec. 22, 2011

(54) THIN FILM SOLAR CELL AND METHOD FOR MANUFACTURING THE SAME

(75) Inventors: Kazufumi SHIOZAWA, Yokohama-shi (JP); Hiroyasu KONDO, Yokohama-shi (JP)

(73) Assignee: KABUSHIKI KAISHA TOSHIBA, Tokyo (JP)

(21) Appl. No.: 13/163,095

(22) Filed: Jun. 17, 2011

(30) Foreign Application Priority Data
Jun. 21, 2010 (JP) 2010-140844

(51) Int. Cl. H01L 31/0232; H01L 31/18

(52) U.S. Cl. 136/259; 438/71; 438/72; 257/E31.128

(57) ABSTRACT

A thin film solar cell includes: a thin film-like substrate; an electrode arranged on the substrate; a photoelectric conversion layer stacked on the electrode; a transparent conductive film arranged on the photoelectric conversion layer; diffraction recessed portions provided periodically on a photoelectric conversion layer-side surface of the electrode; and reflection preventing recessed portions provided periodically on a photoelectric conversion layer-side surface of the transparent conductive film.

### CROSS REFERENCE TO RELATED APPLICATION

This application is based upon and claims the benefit of priority from Japanese Patent Application No. 2010-140844, filed on Jun. 21, 2010; the entire contents of which are incorporated herein by reference.

### FIELD

The present invention relates to a thin film solar cell and a method for manufacturing the same.

### BACKGROUND

In comparison with a bulk solar cell, a thin film solar cell is capable of largely reducing a quantity of materials for use therein, accordingly, is capable of achieving solution of a material shortage problem and large cost reduction, and attracts attention as a next generation solar cell.

However, in the thin film solar cell, photoelectric conversion efficiency thereof is low in comparison with that of the bulk solar cell. This is because, since a thickness of a photoelectric conversion layer is 1 μm or less, a major part of light transmits through the photoelectric conversion layer without being converted into electric energy.

Hence, for the thin film solar cell, there is required a technology for effectively utilizing the light incident onto the photoelectric conversion layer.

A light confinement technology is mentioned as a representative of this technology. As the light confinement technology, three types are well known, which are: reflection prevention; increase of an optical length by a diffraction effect; and electric field enhancement by surface plasmon polariton. The reflection prevention is a technology for increasing a quantity of the light incident onto the photoelectric conversion layer and enhancing the efficiency thereof in such a manner that a structure for decreasing reflection of the light is formed on an interface between the photoelectric conversion layer and a material different therefrom in refractive index. The increase of the optical length by the diffraction effect is a technology for enhancing the photoelectric conversion efficiency by increasing the optical length in the photoelectric conversion layer to increase a light absorption quantity in such a manner that a structure for diffracting the light is formed on the interface between the photoelectric conversion layer and the material different therefrom in refractive index. The surface plasmon polariton is a technology for enhancing the photoelectric conversion efficiency by generating an intensely enhanced electromagnetic field in such a manner that a structure in which the incident light and surface plasmons of metal are coupled to each other on an interface between the photoelectric conversion layer and metal.

Moreover, a wavelength range of solar light usable for the electrophotographic conversion is as wide as 400 to 1100 nm. Therefore, in order to enhance the photoelectric conversion efficiency, it is necessary to enhance absorptance over such a wide wavelength range. However, the light confinement technologies heretofore proposed are technologies which are theoretically established in certain wavelength ranges specific thereto, respectively, and a method necessary to enhance the absorptance over the wide wavelength range of the solar light spectrum has not been proposed before.

### BRIEF DESCRIPTION OF THE DRAWINGS

FIG. 1A is a cross-sectional schematic view obtained by cutting a thin film solar cell according to a first embodiment in a longitudinal direction thereof.

FIG. 1B is a cross-sectional schematic view obtaining by cutting the thin film solar cell according to the first embodiment in parallel to a principal surface thereof.

FIG. 2 is a view explaining an outline of an incident angle of light and the like in the thin film solar cell according to each of the embodiments.

FIGS. 3A to 3K are manufacturing process views No. 1 to No. 11 of the thin film solar cell according to the first embodiment.

FIG. 4 is absorptance of the light with respect to a wavelength of the light in each of a conventional thin film solar cell and the thin film solar cell according to the first embodiment.

FIG. 5 is a relationship between a cycle of reflection preventing recessed portions and reflectance in the thin film solar cell according to the first embodiment.

FIG. 6A is a cross-sectional schematic view obtained by cutting a modification example of the thin film solar cell according to the first embodiment in a longitudinal direction thereof.

FIG. 6B is a cross-sectional schematic view obtained by cutting the modification example of the thin film solar cell according to the first embodiment in parallel to a principal surface thereof.

FIG. 7A is a cross-sectional schematic view obtained by cutting a thin film solar cell according to a second embodiment in a longitudinal direction thereof.

FIG. 7B is a cross-sectional schematic view obtained by cutting the thin film solar cell according to the second embodiment in parallel to a principal surface thereof.

FIGS. 8A to 8C are manufacturing process views No. 1 to No. 3 of the thin film solar cell according to the second embodiment.

### DETAILED DESCRIPTION

A thin film solar cell of each of embodiments includes: a thin film-like substrate; an electrode arranged on the substrate; a photoelectric conversion layer stacked on the electrode; a transparent conductive film arranged on the photoelectric conversion layer; diffraction recessed portions periodically provided on a photoelectric conversion layer-side surface of the electrode; and reflection preventing recessed portions periodically provided on a photoelectric conversion layer-side surface of the transparent conductive film.

A description is made below in detail of the embodiments with reference to the drawings. Note that, in the drawings, the same or similar reference numerals are assigned to those having the same functions or similar functions, and a description thereof is omitted.

### [Thin Film Solar Cell According to First Embodiment]

A description is made below of a structure of a thin film solar cell according to a first embodiment.

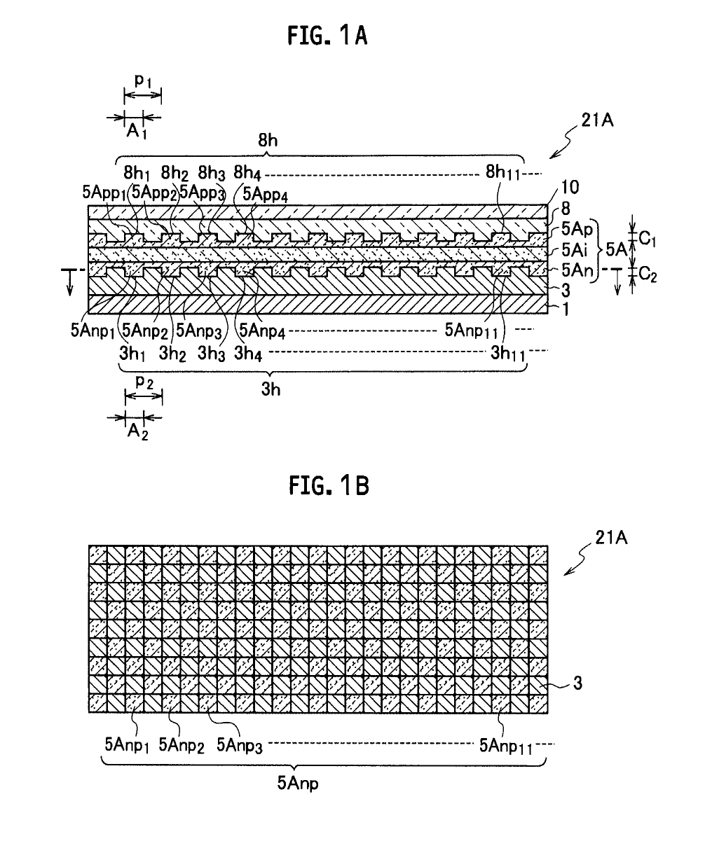

A thin film solar cell 21A according to the first embodiment, which is shown in FIG. 1A, includes: a thin film-like substrate 1; an electrode 3 arranged on the substrate 1; a photoelectric conversion layer 5 (5A) stacked on the electrode 3; and a transparent conductive film 8 arranged on the photoelectric conversion layer 5A. As shown in FIGS. 1A and 1B, the electrode 3 includes diffraction recessed portions 3h (3h₁ to 3h₁₁) provided periodically on a photoelectric conversion layer 5A-side surface thereof. Moreover, the transparent conductive film 8 includes reflection preventing recessed portions 8h (8h₁ to 8h₁₁) provided periodically on a photoelectric conversion layer 5A-side surface thereof. The thin film solar cell 21A further includes a glass substrate 10 arranged on the transparent conductive electrode film 8. Note that, though not shown, the electrode 3 and the transparent conductive film 8 are electrically connected to each other.

The substrate 1 is not particularly limited as long as being thin film-like; however, for example, a thin film-like substrate made of stainless steel can be used as the substrate 1.

Aluminum (Al), silver (Ag) or the like can be used as the electrode 3. More specifically, as the electrode 3, a film or the like can be used, which is obtained by applying a liquid metal material containing nanoparticles of a metal complex of aluminum (Al) or nanoparticles of silver (Ag) on the substrate 1, followed by drying. As the photoelectric conversion layer 5, here, the silicon layer 5A is used, which is formed of three layers, which are an n-type silicon layer 5An, an i-type silicon layer 5Ai and a p-type silicon layer 5Ap. The n-type silicon layer 5An, the i-type silicon layer 5Ai and the p-type silicon layer 5Ap are stacked on the electrode 3 in order from the substrate 1 side. However, materials and structure of the photoelectric conversion layer 5 are not particularly limited as long as the photoelectric conversion layer 5 has a function to convert light into electricity.

As the transparent conductive film 8, an indium tin oxide (ITO) film, a SnO₂ film or the like can be used. More specifically, as the transparent conductive film 8, a film or the like can be used, which is obtained by applying a liquid material containing nanoparticles of ITO, SnO₂ or the like on the silicon layer 5A, followed by drying.

As shown in FIG. 1B, the diffraction recessed portions 3h are arranged in a checkered pattern shape at an equal interval in a longitudinal direction and width direction of the thin film solar cell 21A. An inner shape of each of the diffraction recessed portions 3h, that is, a shape of each of n-type silicon layer protruding portions 5Anp (5Anp₁ to 5Anp₁₁) which enter insides of the diffraction recessed portions 3h is a quadrangular prism shape. The reflection preventing recessed portions 8h also have a similar configuration to that of the diffraction recessed portions 3h. Note that the shape of each of the n-type silicon layer protruding portions 5Anp is not limited to a polygonal prism shape such as the quadrangular prism shape, and may be a cylindrical shape, a conical shape and the like as long as a diffraction effect can be obtained. Moreover, it is not necessary that the n-type silicon layer protruding portions 5Anp₁ to 5Anp₁₁ be in contact with one another, and the n-type silicon layer protruding portions 5Anp₁ to 5Anp₁₁ may be arranged apart from each other in a scattered point fashion. Moreover, it is not necessary that the n-type silicon layer protruding portions 5Anp₁ to 5Anp₁₁ be arranged at an equal interval. The same also applies to the reflection preventing portions 8h.

As shown in FIG. 1A, such a “cycle of the reflection preventing recessed portions 8h” refers to a distance p₁ between left ends of the reflection preventing portions 8h₁ and 8h₂ adjacent to each other. By providing the reflection preventing recessed portions 8h, reflection of solar light with a wavelength range of 400 to 600 nm can be prevented. Here, a width A₁ and depth C₁ of each of the reflection preventing recessed portions 8h₁ to 8h₁₁ are set constant; however, the width A₁ and depth C₁ of each of the reflection preventing recessed portions 8h₁ to 8h₁₁ do not have to be constant as long as the reflection of the solar light can be prevented.

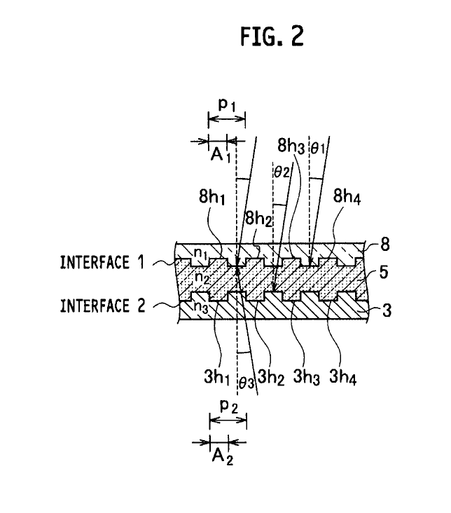

A description is made of the cycle p₁ of the light reflection preventing recessed portions 8h and a cycle p₂ of the diffraction recessed portions 3h while referring to FIG. 2. FIG. 2 is a view explaining outlines of terms such as an incident angle of light in Expressions (1) to (5) shown below.

The cycle p₁ of the reflection preventing recessed portions 8h and the cycle p₂ of the diffraction recessed portions 3h can be obtained by Expression (1) and Expressions (2a) and (2b). Here, Expression (1) represents a condition for allowing the light, which is made incident from an upper surface of the thin film solar cell 21A, to transmit from the transparent conductive film 8 to the photoelectric conversion layer 5 with low reflection. Moreover, Expressions (2a) and (2b) represent conditions for totally reflecting the light, which is reflected by the electrode 3, onto the reflection preventing recessed portions 8h. For the sake of explanation convenience, among the wavelength range of 400 to 1100 nm of the solar light, the wavelength range of 400 to 600 nm is defined as a λ₁ range, a wavelength range of 600 to 800 nm is defined as a λ₂ range, and a wavelength range of 800 to 1100 nm is defined as a λ₃ range.

n₁ sin θ₁±mλ₁/p₁≧n₁ (1)

n₂ sin θ₂±mλ_{2,3}/p₂=n₂ sin θ₃ (2a)

n₂ sin θ₃±mλ_{2,3}/p₁>n₂ (2b)

where n₁ is a refractive index of the transparent conductive film 8, n₂ is a refractive index of the photoelectric conversion layer 5, θ₁ is an incident angle of the light from the transparent conductive film 8 onto the photoelectric conversion layer 5, θ₂ is an incident angle of the light from the photoelectric conversion layer 5 onto the electrode 3, θ₃ is an incident angle of the light from the photoelectric conversion layer 5 onto the transparent conductive film 8, m is an integer, and λ_{1, 2, 3} are wavelengths of the light.

The cycle p₁ of the reflection preventing recessed portions 8h when the depth C₁ of the reflection preventing recessed portions 8h is set at 0.1 μm is preferably less than 0.3 μm, more preferably, less than 0.1 μm.

As shown in FIG. 1A, the “cycle of the diffraction recessed portions 3h” refers to such a distance p₂ between left ends of the diffraction recessed portions 3h₁ and 3h₂ adjacent to each other. By providing the diffraction recessed portions 3h, solar light with a wavelength range of 600 to 1100 nm, which enters an inside of the photoelectric conversion layer 5 of the thin film solar cell 21A, can be diffusely reflected, and can be confined in the thin film solar cell 21A. Moreover, the solar light with the wavelength range of 600 to 800 nm is intensely reinforced in the thin film solar cell 21A by the surface plasmon polariton. As a result, the thin film solar cell 21A can efficiently capture the solar light, and accordingly, power generation efficiency thereof is increased. Here, a width A₂ and depth C₂ of each of the diffraction recessed portions 3h₁ to 3h₁₁ are set constant; however, the width A₂ and the depth C₂ do not have to be constant as long as the solar light can be confined in the thin film solar cell 21A.

The cycle p₂ of the diffraction recessed portions 3h periodically provided on the photoelectric conversion layer 5-side surface of the electrode 3 can be obtained by Expression (3) and Expression (4). Here, Expression (3) represents a condition for propagating, through the photoelectric conversion layer 5, primary diffracted light of the light made incident from the photoelectric conversion layer 5 onto the electrode 3. Moreover, Expression (4) represents a condition for coupling secondary diffracted light, which is made incident from the photoelectric conversion layer 5 onto the electrode 3, to surface plasmons of the electrode 3.

n₂ sin θ₂±m₁λ₂/p₂=n₂ sin θ₃±m₂λ₂/p₂ (3)

n₂ sin θ₃±m₂λ₂/p₂={(n₁²·n₂²)/(n₁²·n₂²)}^{1/2} (4)

where n₂ is a refractive index of the photoelectric conversion layer 5, θ₂ is an incident angle of the light from the photoelectric conversion layer 5 onto the electrode 3, θ₃ is a diffraction angle of the primary diffracted light, m₁ is equal to 1, m₂ is equal to 2, and λ₂ is a wavelength of the light.

Moreover, at the same time when Expression (4) is established, Expression (5) is established, which is a condition for coupling the primary diffracted light to the surface plasmons when the primary diffracted light of the case of coupling the secondary diffracted light to the surface plasmons propagates through the photoelectric conversion layer 5, is totally reflected on the reflection prevention recessed portions 8h, and is made incident onto the electrode 3.

n₂ sin θ₃±m₁λ₂/p₂={(n₁²·n₂²)/(n₁²+n₂²)}^{1/2} (5)

As described above, a structure of coupling the secondary diffracted light to the surface plasmons is adopted, whereby an effect of propagating the primary diffracted light through the photoelectric conversion layer 5 and increasing an optical length is obtained. In addition, an effect of enhancing the electric field, which is obtained by the surface plasmons, is increased.

Supposing a structure of coupling the primary diffracted light to the surface plasmons is adopted, then the effect of propagating the diffracted light through the photoelectric conversion layer 5 and increasing the optical length is not obtained. Moreover, if a structure of coupling tertiary diffracted light to the surface plasmons is adopted, then the effect of enhancing the electric field, which is obtained by the surface plasmons, is decreased.

### [Method for Manufacturing Thin Film Solar Cell According to First Embodiment]

A description is made below of a method for manufacturing the thin film solar cell 21A according to the first embodiment.

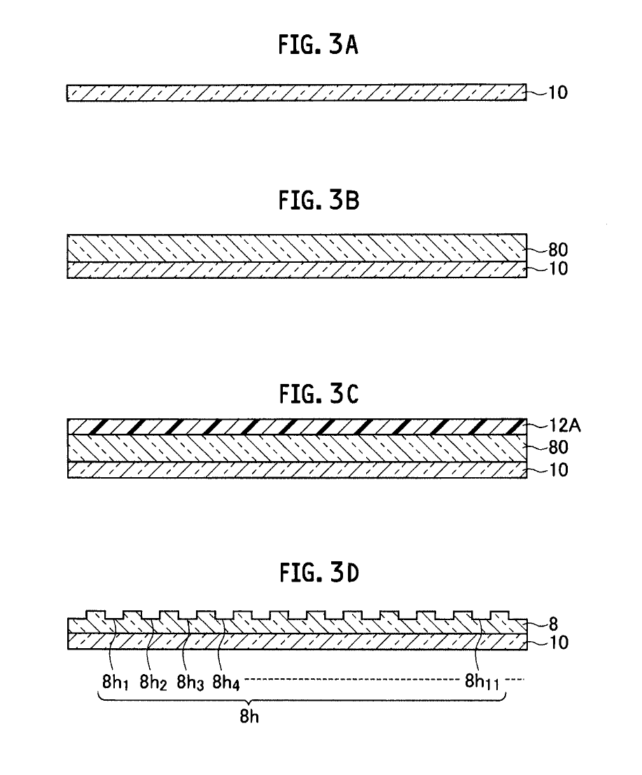

(i) As shown in FIG. 3A, the thin plate-like glass substrate 10 is prepared.
(ii) As shown in FIG. 3B, a transparent conductive film material 80 is formed on the glass substrate 10.
(iii) As shown in FIG. 3C, on the transparent conductive film material 80, there is arranged a resist film 12A including openings at spots corresponding to the reflection preventing recessed portions 8h in FIG. 1B, and thereafter, the transparent conductive film material 80 is etched. Then, as shown in FIG. 3D, on the glass substrate 10, there is formed the transparent conductive film 8 including the reflection preventing recessed portions 8h periodically on an opposite surface thereof with the glass substrate 10.
(iv) As shown in FIG. 3E, the p-type silicon layer 5Ap is stacked on the transparent conductive film 8. Thereafter, as shown in FIG. 3F, the i-type silicon layer 5Ai is stacked on the p-type silicon layer 5Ap. Moreover, as shown in FIG. 3G, an n-type silicon layer 50An is stacked on the i-type silicon layer 5Ai. Then, as shown in FIG. 3H, on the n-type silicon layer material 50An, there is arranged a resist film 12B including openings at spots corresponding to the diffraction recessed portions 3h, thereafter, the n-type silicon layer material 50An is etched, and the n-type silicon layer 5An is formed. Then, as shown in FIG. 3I, on the transparent conductive film 8, there is formed the photoelectric conversion layer 5 (5A) including the reflection preventing recessed portions 8h periodically on an opposite surface thereof with the transparent conductive film 8.
(v) Thereafter, as shown in FIG. 3J, the electrode 3 is deposited on the n-type silicon layer 5An. Moreover, as shown in FIG. 3K, the substrate 1 is deposited on the electrode 3.

In such a manner as described above, the thin film solar cell 21A according to the first embodiment in FIG. 1A is manufactured. In the above-described steps (1) to (v), the methods for forming the respective layers are not particularly limited; however, for example, a plasma-enhanced chemical vapor deposition (PE-CVD method) and the like can be used. Growth conditions and the like of the respective layers are appropriately determined based on the materials to be deposited, and the like.

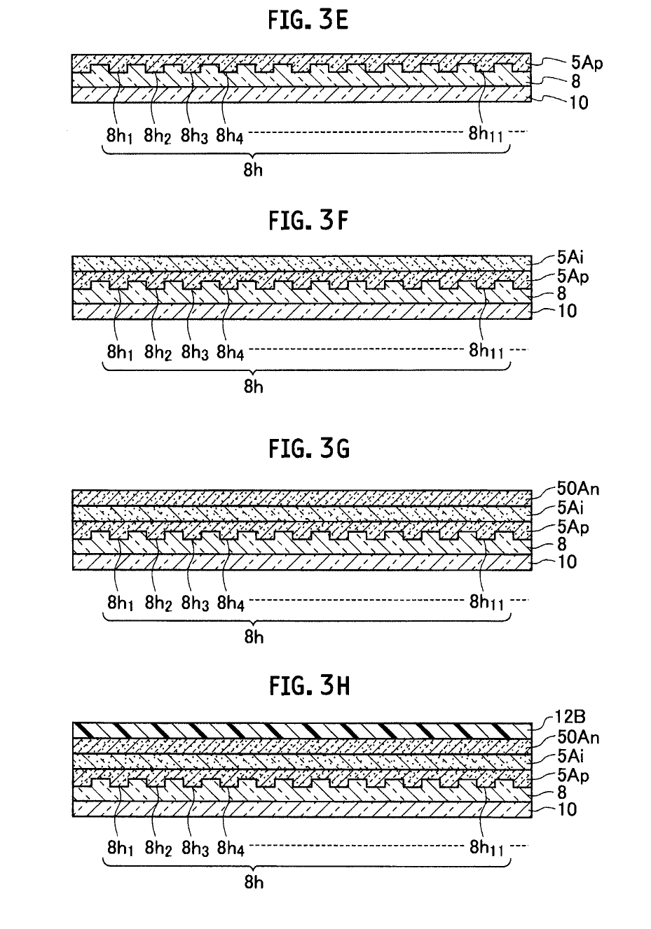

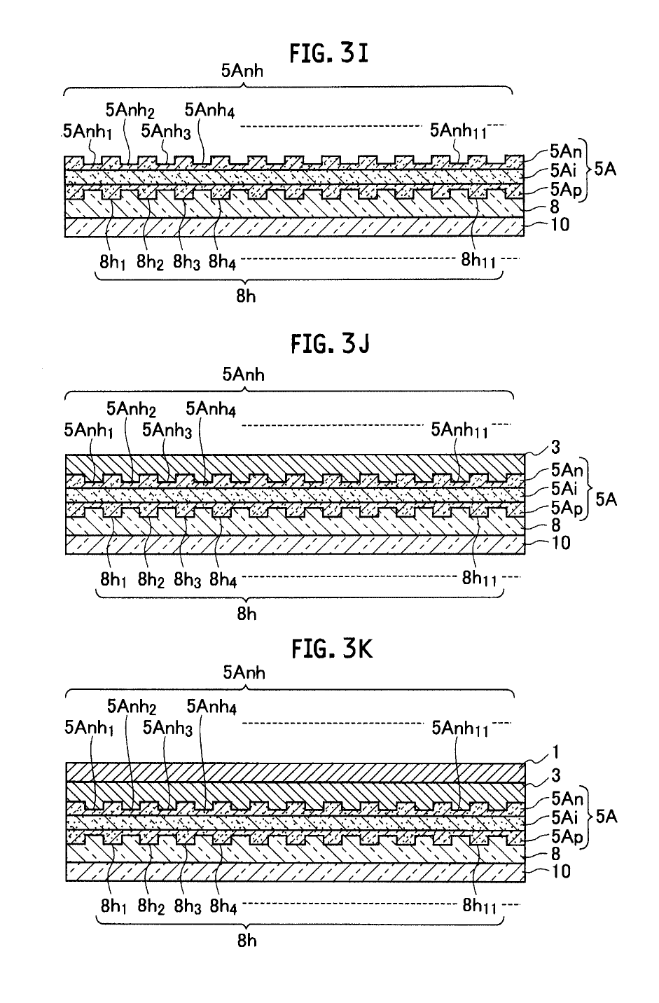

In accordance with the first embodiment, the reflection preventing recessed portions 8h and the diffraction recessed portions 3h are provided, whereby absorptance of the light is enhanced over a wide wavelength range. By using FIGS. 4 and 5, a description is made of functions and effects of the first embodiment in combination with differences of the solar cell according to the first embodiment from the conventional thin film solar cell.

FIG. 4 shows relationships between the wavelength of the light and the absorptance of the light in each of the conventional thin film solar cell and the thin film solar cell according to the first embodiment. In FIG. 4, a solid line represents experimental results at the time when the solar light is made vertically incident onto the thin film solar cell 21A according to the first embodiment when the cycle p₁ of the reflection preventing recessed portions 8h is set at 0.1 μm, and when the cycle p₂ of the diffraction recessed portions 3h is set at 0.3 μm. A broken line represents experimental results at the time when the solar light is made vertically incident onto the conventional thin film solar cell manufactured in a similar way to the thin film solar cell 21A except that the reflection preventing recessed portions 8h and the diffraction recessed portions 3h are not provided. For the sake of explanation convenience, among the wavelength range of 400 to 1100 nm of the solar light, the wavelength range of 400 to 600 nm is defined as the λ₁ range, the wavelength range of 600 to 800 nm is defined as the λ₂ range, and the wavelength range of 800 to 1100 nm is defined as the λ₃ range.

As shown in FIG. 4, in the conventional thin film solar cell, the absorptance was sharply decreased from the wavelength of 600 nm as a peak toward all of the λ₁ range, the λ₂ range and the λ₃ range. A cause of the absorptance decrease is as follows. Specifically, in the λ₁ range, though the absorption coefficient of the photoelectric conversion layer 5 is sufficiently high, a difference in refractive index between the transparent conductive film 8 and the photoelectric conversion layer 5 is large, and reflectance in the conventional thin film solar cell is as high as approximately 20%. It is therefore conceived that, without being sufficiently absorbed to the photoelectric conversion layer 5, the light is reflected thereon, and is discharged to the outside.

Meanwhile, in accordance with the thin film solar cell 21A of the first embodiment, the reflection preventing recessed portions 8h are periodically provided on the photoelectric conversion layer 5-side surface of the transparent conductive film 8, whereby an effect of preventing the reflection of the light is obtained. As a result, in the λ₁ range, the absorptance of the light was enhanced more than heretofore. Moreover, the diffraction recessed portions 3h are provided on the photoelectric conversion layer 5-side surface of the electrode 3, whereby, in the λ₂ range, the absorptance of the light was enhanced more than heretofore by the effect of the surface plasmons, and further, in the λ₃ range, the absorptance of the light was enhanced more than heretofore by the diffraction effect of the light.

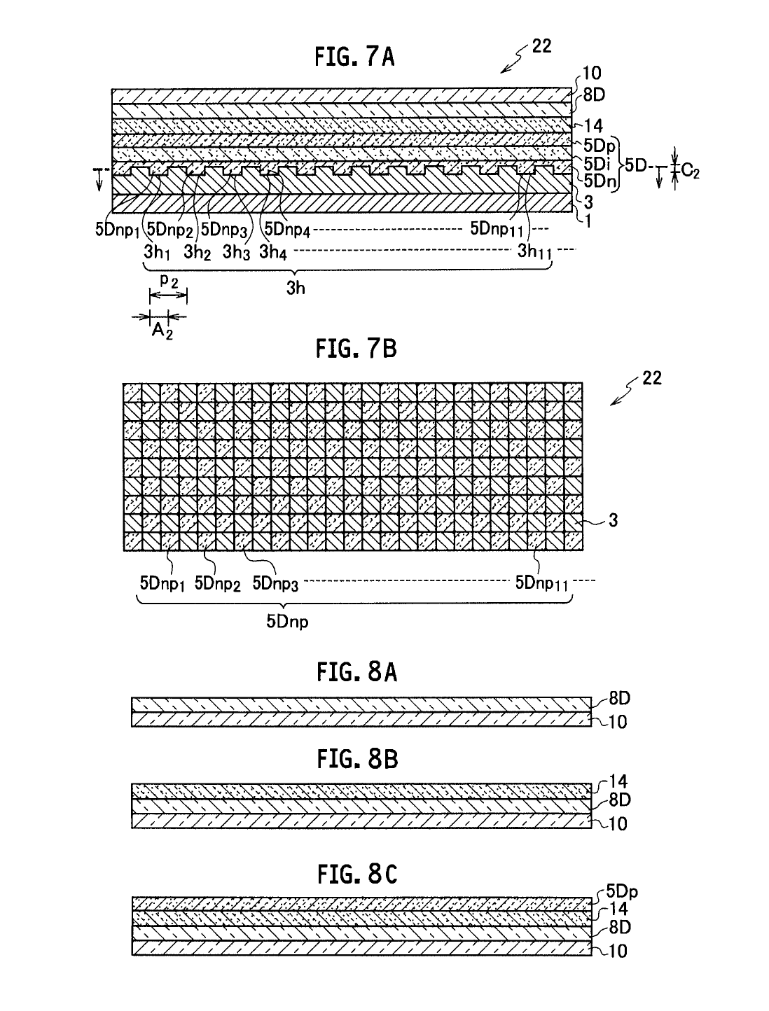

Next, FIG. 5 shows a relationship between the cycle p₁ of the reflection preventing recessed portions 8h and reflectance in the thin film solar cell 21A when light with a wavelength of 500 nm is irradiated thereonto. The depth C₁ of the reflection preventing recessed portions 8h was set at 0.1 μm, and only the cycle p₁ was changed. A dotted line represents reflectance when the light with the wavelength of 500 nm was irradiated onto a thin film solar cell including a similar structure to that of the thin film solar cell 21A except that the reflection preventing recessed portions 8h were not provided. As shown in FIG. 8, the reflection preventing recessed portions 8h were provided, whereby the reflectance of the light was decreased. Moreover, in a range where the cycle p₁ of the reflection preventing recessed portions 8h was less than 0.3 μm, the reflectance of the light became substantially 0%.

As described above, in accordance with the first embodiment, the thin film solar cell is obtained, in which the absorptance of the solar light having the wide wavelength range of 400 to 1100 nm is high, and in addition, the photoelectric conversion efficiency is high.

### Modification Example of First Embodiment

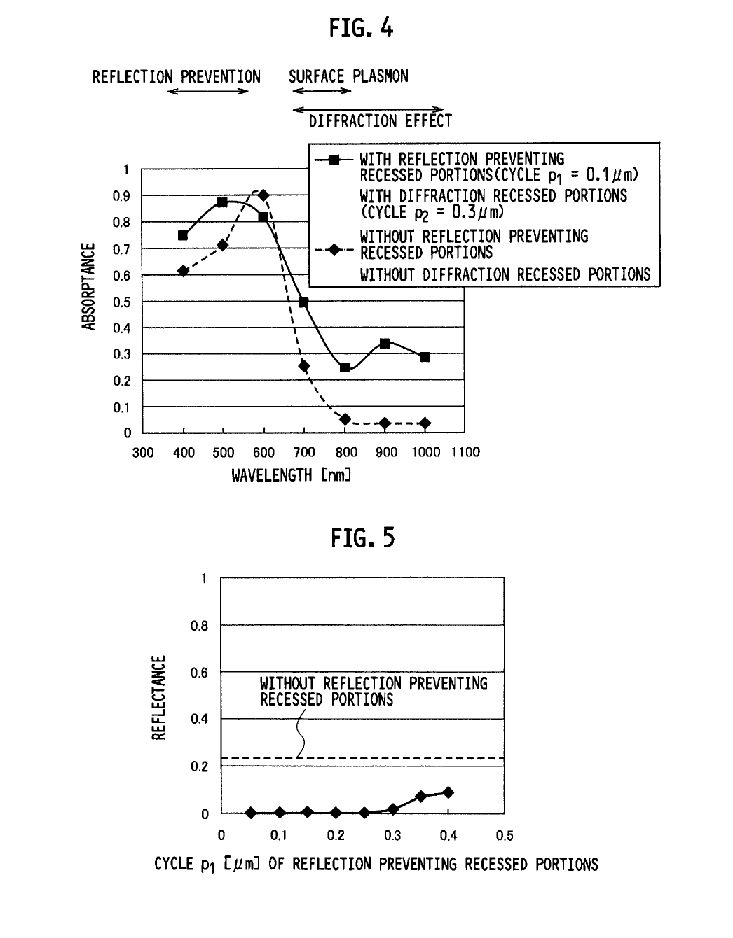

In the first embodiment, as the photoelectric conversion layer 5, the silicon layer 5A that was a single layer was used. However, from a viewpoint of efficiently converting the solar light with the wide wavelength range into electric power, it is preferable that a plurality of silicon layers be provided between the electrode 3 and the transparent conductive film 8. Specifically, as shown in FIG. 6A, on an amorphous silicon layer 5C provided on the electrode 3, a polycrystalline silicon layer 5B may be provided while sandwiching a buffer layer 13 therebetween. A reason for this is as follows. The polycrystalline silicon layer 5B and the amorphous silicon layer 5C compensate light absorption wavelengths of each other, whereby an absorption wavelength range of the light is widened, absorption efficiency of the light is enhanced, and consequently, the efficiency of the photoelectric conversion is enhanced. From a viewpoint of facilitating a manufacturing process, it is preferable that an i-type polycrystalline silicon layer be used as an i-type silicon layer 5Bi as a lowermost layer on the glass substrate 10 side in the case where the respective layers are sequentially stacked on the glass substrate 10.

### [Thin Film Solar Cell According to Second Embodiment]

A description is made below of a structure of a thin film solar cell according to a second embodiment.

In the thin film solar cell 21A according to the first embodiment, the reflection preventing recessed portions 8h are periodically provided on the interface between the transparent conductive film 8 and the photoelectric conversion layer 5 (5A), whereby the reflection of the light is prevented. However, in place of providing the reflection preventing recessed portions 8h, as shown in FIG. 6A, a reflection preventing layer 14 is provided between the photoelectric conversion layer 5 (5D) and the transparent conductive film 8D, whereby the reflection of the light can also be prevented. A description is made of the second embodiment while focusing different points thereof from the first embodiment.

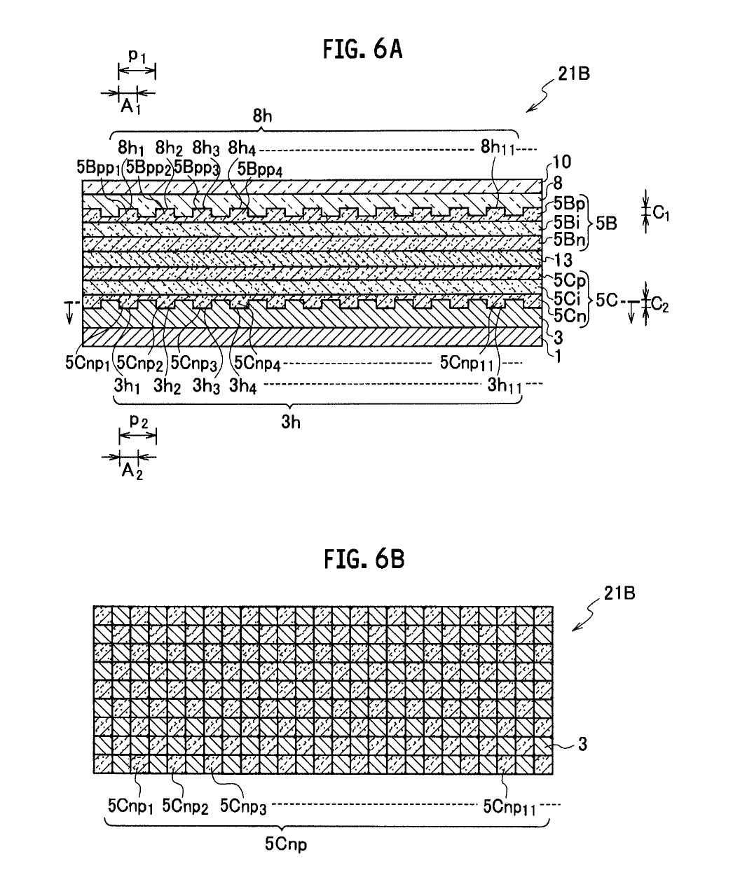

A thin film solar cell 22 according to the second embodiment, which is shown in FIG. 7A, includes: a thin film-like substrate 1; an electrode 3 arranged on the substrate 1; the photoelectric conversion layer 5 (5D) stacked on the electrode 3; the reflection preventing layer 14 arranged on the photoelectric conversion layer 5D; and the transparent conductive film 8D arranged on the reflection preventing layer 14. As shown in FIGS. 7A and 7B, the electrode 3 includes diffraction recessed portions 3h (3h₁ to 3h₁₁) periodically on a photoelectric conversion layer 5D-side surface thereof. The thin film solar cell 22 further includes a glass substrate 10 arranged on the transparent conductive film 8D. Note that, though not shown, the electrode 3 and the transparent conductive film 8D are electrically connected to each other.

A film thickness d and refractive index n₄ of the reflection preventing layer 14 can be obtained by Expressions (6) and (7).

n₄d=λ₁/4 (6)

n₄=(n₁·n₂)^{1/2} (7)

By providing the reflection preventing layer 14, the thin film solar cell 22 according to the second embodiment can suppress the reflection of the light with the wavelength range of 400 to 600 nm, and can efficiently capture the solar light.

### [Method for Manufacturing Thin Film Solar Cell According to Second Embodiment]

A description is made below of a method for manufacturing the thin film solar cell 22 according to the second embodiment.

(i) The thin plate-like glass substrate 10 as shown in FIG. 3A is prepared.
(ii) As shown in FIG. 8A, the transparent conductive film 8D is formed on the glass substrate 10.
(iii) As shown in FIG. 8B, the reflection preventing layer 14 is formed on the transparent conductive film 8D.
(iv) As shown in FIG. 8C, a p-type silicon layer 5Dp is stacked on the reflection preventing layer 14.
(v) Thereafter, similar steps to those in FIGS. 3F to 3K are performed.

In such a manner as described above, the thin film solar cell 22 according to the second embodiment is manufactured.

As described above, in accordance with the second embodiment, in a similar way to the first embodiment, the thin film solar cell is obtained, in which the absorptance of the solar light having the wide wavelength range of 400 to 1100 nm is high, and in addition, the photoelectric conversion efficiency is high.

### Other Embodiments

As above, the present invention has been described by the embodiments; however, it should not be understood that the description and the drawings, which form a part of this disclosure, limit this invention. From this disclosure, varieties of alternative embodiments, examples and application technologies will be obvious for those killed in the art.

In the first embodiment, the PE-CVD method has been described as an example of the method for forming the respective layers; however, besides this, a method of applying the liquid material in a pattern fashion may be used. As an applying method, there is mentioned a method of applying the liquid material in the pattern fashion by using a general liquid droplet applying device such as an ink-jet device, a dispenser, a micro-dispenser and a slit coater. For example, in the steps of FIGS. 3E to 3G, as the silicon layer 5A, a film may be obtained by applying a solution containing polysilane by an ink-jet method or the like under an inert gas atmosphere, followed by drying. At this time, after the i-type silicon layer 5Ai is installed in a plasma generating device, preferably, the i-type silicon layer 5Ai is subjected to hydrogen treatment, for example, dangling bond reduction treatment by being exposed to hydrogen plasma or atmospheric hydrogen plasma, and so on.

Moreover, in the case of using such a pattern applying method, in the step of FIG. 3C, a nano-imprinted substrate including a pattern of protrusions corresponding to the reflection preventing recessed portions 8h in FIG. 1B may be formed on the surface of the transparent conductive film 8 by a nano-imprint method of thrusting the nano-imprinted substrate concerned against the transparent conductive film material 80. In a similar way, in the step of FIG. 3H, after the n-type silicon layer material 50An is applied, a nano-imprinted substrate including a pattern of protrusions corresponding to the diffraction recessed portions 3h is thrust against the surface of the n-type silicon layer material 50An, then the n-type silicon layer 5An is formed by drying thereof, and the electrode 3 including the diffraction recessed portions 3h may be formed by subsequent application (deposition) thereof.

Moreover, in the second embodiment, in place of the reflection preventing recessed portions 8h of the first embodiment, the reflection preventing layer 14 is provided between the photoelectric conversion layer 5 (5D) and the transparent conductive film 8D; however, the first embodiment and the second embodiment may be combined with each other. That is to say, after reflection preventing recessed portions 8Dh are provided on the surface of the transparent conductive film 8D, the reflection preventing layer 14 may be provided on the reflection preventing recessed portions 8Dh.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A thin film solar cell comprising:
a thin film-like substrate;
an electrode arranged on the substrate;
a photoelectric conversion layer stacked on the electrode;
a transparent conductive film arranged on the photoelectric conversion layer;
diffraction recessed portions provided periodically on a photoelectric conversion layer-side surface of the electrode; and
reflection preventing recessed portions provided periodically on a photoelectric conversion layer-side surface of the transparent conductive film.

2. A thin film solar cell comprising:
a thin film-like substrate;
an electrode arranged on the substrate;
a photoelectric conversion layer stacked on the electrode;
a transparent conductive film arranged above the photoelectric conversion layer;
diffraction recessed portions provided periodically on a photoelectric conversion layer-side surface of the electrode; and
a reflection preventing layer provided between the photoelectric conversion layer and the transparent conductive film.

3. The thin film solar cell according to claim 1,
wherein a cycle p₁ of the reflection preventing recessed portions is determined by Expressions (1) and (2b):
n₁ sin θ₁±mλ₁/p₁≧n₁ (1)
n₂ sin θ₃±mλ₁/p₁>n₂ (2b)
(where n₁ is a refractive index of the transparent conductive film, n₂ is a refractive index of the photoelectric conversion layer, θ₁ is an incident angle of light from the transparent conductive film onto the photoelectric conversion layer, θ₃ is an incident angle of the light from the photoelectric conversion layer onto the transparent conductive film, m is an integer, and λ₁ is a wavelength of the light).

4. The thin film solar cell according to either one of claims 1 and 2,
wherein a cycle p₂ of the diffraction recessed portions is determined by Expressions (3) to (5):
n₂ sin θ₂±m₁λ_{2,3}/p₂=n₂ sin θ₃±m₂λ_{2,3}/p₂ (3)
n₂ sin θ₃±m₂λ₂/p₂={(n₁²·n₂²)/(n₁²+n₂²)}^{1/2} (4)
n₂ sin θ₃±m₁λ₂/p₂={(n₁²·n₂²)/(n₁²+n₂²)}^{1/2} (5)
(where n₂ is a refractive index of the photoelectric conversion layer, θ₂ is an incident angle of light from the photoelectric conversion layer onto the electrode, θ₃ is a diffraction angle of primary diffracted light made incident from the photoelectric conversion layer onto the electrode, m₁ is equal to 1, m₂ is equal to 2, λ₂ is a wavelength (600 to 800 nm) of the light, and λ₃ is a wavelength (800 to 1100 nm) of the light).

5. The thin film solar cell according to claim 2,
wherein a film thickness d and refractive index n₄ of the reflection preventing layer are determined by Expressions (6) and (7):
n₄d=λ₁/4 (6)
n₄=(n₁·n₂)^{1/2} (7).

6. The thin film solar cell according to either one of claims 1 and 2,
wherein the photoelectric conversion layer is a silicon layer in which an n-type silicon layer, an i-type silicon layer and a p-type silicon layer are stacked in order from the substrate side.

7. The thin film solar cell according to claim 6,
wherein a plurality of the silicon layers are provided between the electrode and the transparent conductive film, one of the i-type silicon layers is an i-type amorphous silicon layer, and one of the i-type silicon layers is an i-type polycrystalline silicon layer.

8. A method for manufacturing a thin film solar cell, comprising the steps of:
forming a transparent conductive film on a glass substrate;
forming reflection preventing recessed portions periodically on a surface of the transparent conductive film, the surface being opposite with the glass substrate;
forming a photoelectric conversion layer on the transparent conductive film on which the reflection preventing recessed portions are formed;
forming diffraction recessed portions periodically on a surface of the photoelectric conversion layer, the surface being opposite with the transparent conductive film;
forming an electrode on the photoelectric conversion layer on which the diffraction recessed portions are formed; and
forming a substrate on the electrode.

9. A method for manufacturing a thin film solar cell, comprising the steps of:
forming a transparent conductive film on a glass substrate;
forming a reflect ion preventing layer on the transparent conductive film;
forming a photoelectric conversion layer on the reflection preventing layer;
forming diffraction recessed portions periodically on a surface of the photoelectric conversion layer, the surface being opposite with the transparent conductive film;
forming an electrode on the photoelectric conversion layer on which the diffraction recessed portions are formed; and
forming a substrate on the electrode.
